(19) United States
(12) Patent Application Publication
(10) Pub. No.: US 2006/0292776 A1
(43) Pub. Date: Dec. 28, 2006

(54) Strained field effect transistors

(76) Inventors: Been-Yih Jin, Lake Oswego, OR (US); Robert S. Chau, Beaverton, OR (US); Suman Datta, Beaverton, OR (US); Brian S. Doyle, Portland, OR (US); Jack T. Kavalieros, Portland, OR (US); Justin K. Brask, Portland, OR (US); Mark L. Doczy, Beaverton, OR (US); Matthew V. Metz, Hillsboro, OR (US); Markus Kuhn, Portland, OR (US); Marko Radosavlievic, Beaverton, OR (US); M. Reaz Shaheed, Beaverton, OR (US); Patrick H. Keys, Portland, OR (US)

Correspondence Address: TROP PRUNER & HU, PC, 1616 S. VOSS ROAD, SUITE 750, HOUSTON, TX, 77057-2631, US

(21) Appl. No.: 11/167,647

(22) Filed: Jun. 27, 2005

(51) Int. Cl. H01L 21/8234; H01L 21/20; H01L 21/336

(52) U.S. Cl. 438/197; 438/303; 438/301; 438/478

(57) ABSTRACT

An NMOS transistor may be formed with a biaxially strained silicon upper layer having a thickness of greater than 500 Angstroms. The resulting NMOS transistor may have good performance and may exhibit reduced self-heating. A PMOS transistor may be formed with both a biaxially and uniaxially strained silicon germanium layer. A source substrate bias applied to both NMOS and PMOS transistors can enhance their performance.

### BACKGROUND

This invention relates generally to field effect transistors and, particularly, to such transistors having strained layers in the channel regions.

Strain may be used to enhance electron and hole mobility. For example, biaxial tensile strain may be produced in silicon to enhance the electron mobility by depositing a silicon cap layer on top of a silicon germanium base layer. Since the lattice structure of the silicon germanium base layer is larger than that normally found in silicon, the deposition of the silicon on top of the base layer stretches the silicon lattice in the plane parallel to the plane of the underlying silicon germanium containing layer. This induces biaxial strain and results in tensile stress higher than 1 GPa in the silicon cap layer.

One issue with bi-axially strained layers is called self-heating. Self-heating is the generation of heat by a transistor as it conducts current. As the transistor continues to conduct current, it heats itself, raising its temperature. This increased temperature reduces the performance of the transistor. The thick relaxed silicon germanium layer used in producing the tensile strain in the silicon layer, for example, has thermal conductivity ten times lower than a silicon layer, hence causing more serious self heating problem.

To produce a biaxial compressively strained channel, the same lattice mismatch property between silicon and silicon germanium can be used. In one case, a thin silicon germanium deposited on top of silicon. Where the larger silicon germanium accommodate to the underlying small lattice of silicon and results in compressive strain in the silicon germanium layer. In another case, silicon germanium is grown in a recessed source/drain region, exerts uniaxial compressive stress toward the channel region from both sides of the channel region, creating compressive stress in the channel region.

As complementary metal oxide semiconductor transistors become increasingly smaller, to improve density and electrical performance, the physical gate thickness has been aggressively scaled, along with the transistor gate length. However, reducing the physical thickness of the gate oxide, increases gate oxide leakage due to tunneling. A high dielectric constant gate oxide can be used in place of silicon dioxide to reduce the gate oxide leakage problem. Since a physically thicker high dielectric constant gate oxide can provide equivalent electrical control, at the channel surface, to a much thinner silicon dioxide gate oxide, the gate leakage through gate oxide may be reduced.

### BRIEF DESCRIPTION OF THE DRAWINGS

FIG. 1 is an enlarged, cross-sectional depiction of an NMOS transistor in accordance with one embodiment of the present invention;

FIG. 2 is an enlarged, cross-sectional view corresponding to FIG. 1 at an early stage of manufacture;

FIG. 3 is an enlarged, cross-sectional view at a subsequent stage of manufacture in accordance with one embodiment of the present invention;

FIG. 4 is an enlarged, cross-sectional view at a subsequent stage of manufacture in accordance with one embodiment of the present invention;

FIG. 5 is an enlarged, cross-sectional view at a subsequent stage in accordance with one embodiment of the present invention;

FIG. 6 is an enlarged, cross-sectional view at a subsequent stage of manufacture in accordance with one embodiment of the present invention;

FIG. 7 is an enlarged, cross-sectional view of a PMOS transistor at an early stage of manufacture;

FIG. 8 is an enlarged, cross-sectional view of the embodiment shown in FIG. 7 at a subsequent stage of manufacture in accordance with one embodiment of the present invention;

FIG. 9 is an enlarged, cross-sectional view of another embodiment of a PMOS transistor at an early stage of fabrication;

FIG. 10 is an enlarged, cross-sectional view at a subsequent stage of manufacture in accordance with one embodiment of the present invention;

FIG. 11 is an enlarged, cross-sectional view of another embodiment of the present invention; and

FIG. 12 is an enlarged, cross-sectional view of another embodiment of the present invention;

### DETAILED DESCRIPTION

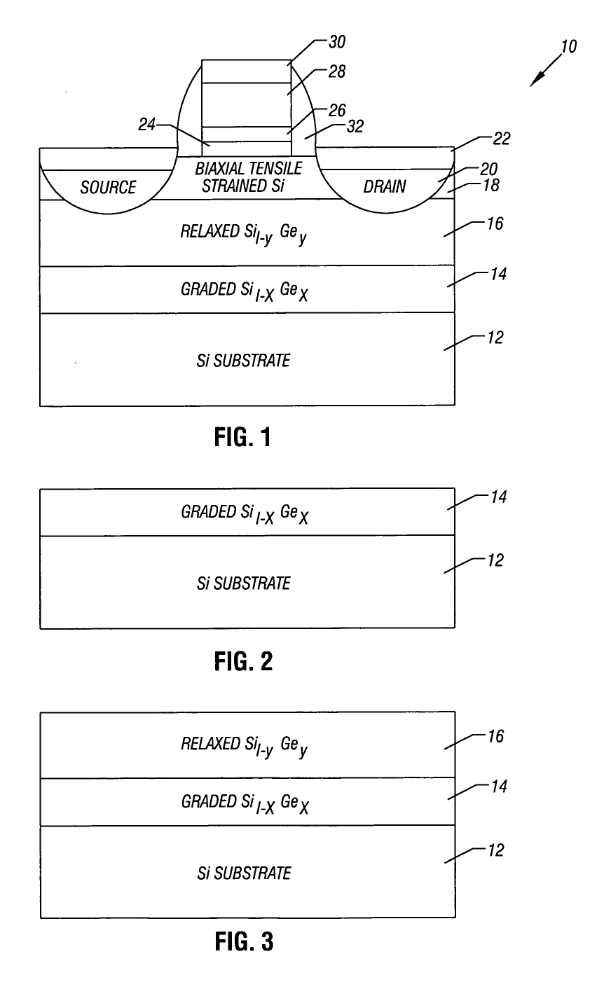

Referring to FIG. 1, an NMOS transistor 10 may be formed on a silicon substrate 12. A graded silicon germanium layer 14 may be formed over the substrate 12. The graded layer 14 may be formed so that the germanium concentration increases from the bottom to the top of the layer 14. The graded layer 14 may have the formula Si₁₋ₓGeₓ

Over the layer 14 may be a relaxed silicon germanium layer 16. The layer 16 may have the formula Si_{1-y}Ge_{y}. Over the layer 16 may be formed a biaxial tensile strained silicon layer 18. As described previously, the epitaxial deposition of the silicon layer 18 on the silicon germanium layer 16 results in biaxial tensile strain. Basically, the silicon layer 18 is strained in the x and y directions, parallel to the plane of the layer 16, because its lattice is forced to matches the size of the larger silicon germanium lattice of the layer 16. At the same time, in the direction transverse to the plane of the layer 16, the silicon layer 18 lattice may be shrunk.

A source and drain 20 may be formed through the silicon layer 18 and into the relaxed silicon germanium layer 16. Salicide contacts 22 may be formed on the source and drain 20 in one embodiment of the present invention.

A gate stack may include, in one embodiment, a salicide contact 30, a polysilicon layer 28, a metal layer 26, and a high dielectric constant gate oxide 24. The oxide 24 may have a gate dielectric constant greater than 10 in one embodiment of the present invention. A sidewall spacer 32 may be formed over the sides of the gate structure.

In one embodiment of the present invention, the thickness of the layer 18 is at least about 500 Angstroms. At thicknesses of about 500 Angstroms and greater, the thermal conductivity of the layer 18 is effective to reduce self-heating. In some embodiments of the present invention, the layer 18 may be as thick as 2000 Angstroms. The layer 18 may be as thick as 2000 Angstroms in some embodiments without releasing all the strain upon thermal processing.

The graded layer 14, in some embodiments, may be graded from zero percent germanium (x) at the silicon substrate 12 to y percent at the top where the relaxed layer 16 is formed. The grading of the layer 14 may reduce the dislocation density in the active channel area. Thus, the germanium concentration x may be gradually increased from the surface over the silicon substrate 12, up to that germanium concentration y, exhibited by the layer 16.

In some embodiments, the use of a high dielectric gate oxide 24 and a metal gate 26 may reduce the thermal anneal of the strained silicon layer 18, ensuring that more of the strain is retained after thermal processing. The thick silicon layer 18 may be an epitaxial layer having sufficient thermal conductivity to reduce the self-heating effect due to the poor thermal conductivity of silicon germanium graded and relaxed underlying layers. In other words, heat may be conducted upwardly out of the transistor despite the fact that the layers underlying the layer 18 may be relatively poor thermal conductors.

As a result, the electrical performance, including drive current, may be improved through mobility enhancement. The mobility enhancement arises from the biaxial strain, exerted by the silicon germanium relaxed layer 16, without suffering a loss of performance due to self-heating in some embodiments.

As one example, the strained silicon layer 18 may be grown on a relaxed layer 16, having the formula Si_{0.85}Ge_{0.15} and a graded layer 14, which goes from 0 to 15% germanium. A 2100 Angstrom silicon layer 18 may have a thermal conductivity of about 1.5 W/(cm. deg.) based on simulated data.

Referring to FIG. 2, the graded layer 14 may be deposited with increasing germanium concentration on the silicon substrate 12. In one embodiment, the grading rate may be less than one percent per 1000 Angstroms. The deposition may be done, in one embodiment, using low pressure chemical vapor deposition using SiH₄, di-chlorosilane or tri-chlorosilane as the silicon source and geramane as the germanium source. A pressure range from 1 Torr to 100 Torr and a temperature range from 500° to 800° C. may be used in one embodiment.

Referring to FIG. 3, the relaxed silicon germanium layer 16 may be deposited with a constant germanium concentration. In one embodiment, a low pressure chemical vapor deposition method may be used as described for forming the graded layer 14. Generally, the lower the germanium concentration of the layer 16, the thicker the layer should be. For example, with a germanium concentration of ten percent, the layer 16 may be greater than one micron thick. For a germanium concentration of about thirty percent, the layer 16 may be greater than 5000 Angstroms thick.

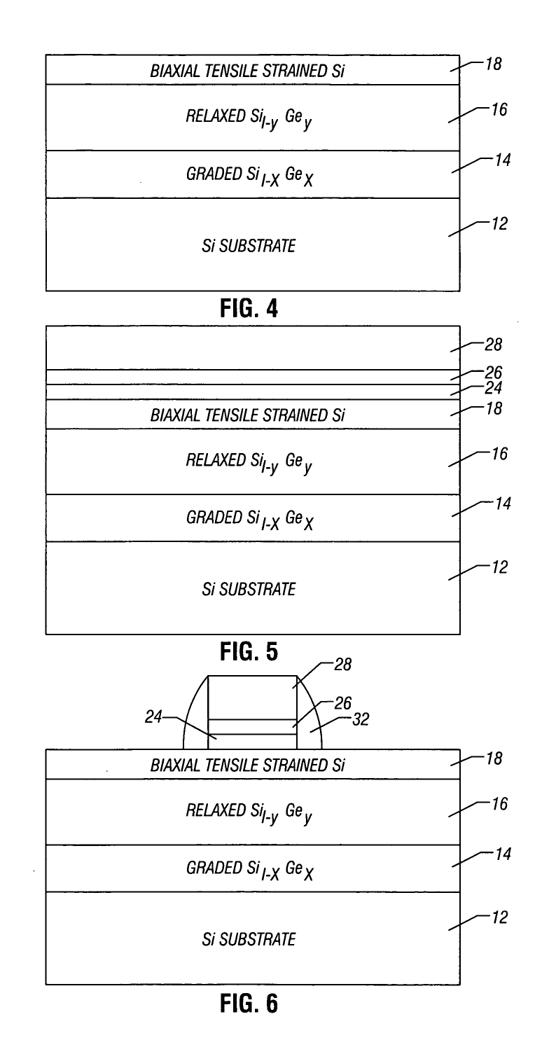

Referring to FIG. 4, following the formation of the relaxed silicon germanium layer 16, a thick silicon tensile strained layer 18 may be deposited using low pressure chemical vapor deposition in one embodiment. The deposition may be done with SiH₄, di-chlorosilane or tri-chlorosilane as a silicon source. Low temperature deposition (e.g., at a temperature less than 700° C.) may be used to improve the strain retention of the tensile strained silicon layer 18 post high temperature anneal.

Then, referring to FIG. 5, a high dielectric constant (greater than 10) gate oxide 24 can be deposited in one embodiment. The gate oxide 24 may, for example, be hafnium oxide, zirconium oxide, or aluminum oxide, to mention a few examples. A metal gate layer 26 and polysilicon layer 28 can then be deposited. The metal gate layer 26 can include hafnium, zirconium, or aluminum, as examples. The gate can be defined by a dry etch and the exposed high dielectric constant gate oxide 24 can be removed with a wet etch. A spacer 32 can be formed on the gate sidewalls by a spacer deposition and etch back.

The resulting structure is shown in FIG. 6. Then, the source/drain areas may be defined, for example, by ion implantation and salicide formation in one embodiment. Contact and metallization may be formed by conventional methods. In some embodiments of the present invention, the silicon layer 18 may have a thermal conductivity of at least 0.2 W/(cm. deg.).

In some embodiments, a PMOS structure may be formed using any suitable process. It may be conventional in some embodiments of the present invention.

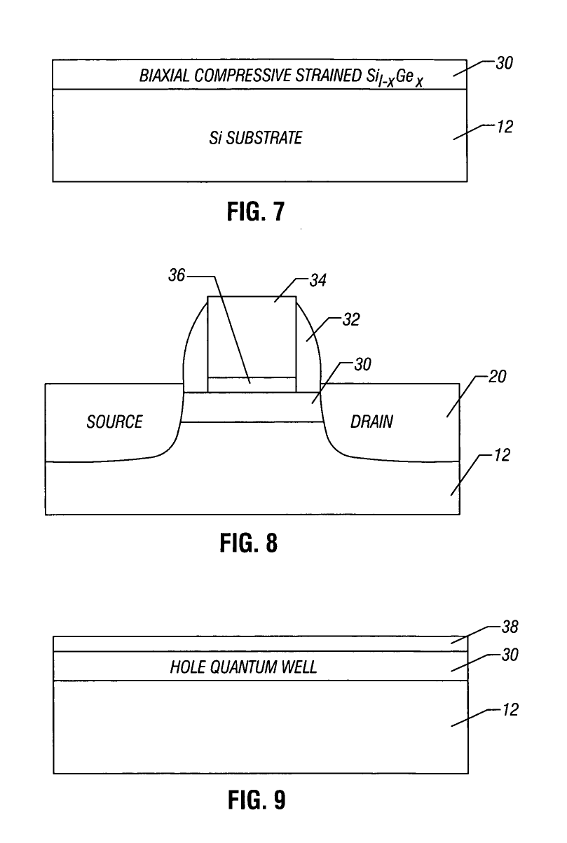

Referring to FIG. 7, the fabrication of a PMOS transistor, in accordance with another embodiment of the present invention, is illustrated. The PMOS transistor, shown in FIGS. 7 and 8, may be used in a conventional complementary metal oxide semiconductor process.

The substrate 12 may be a substantially silicon substrate. A biaxial compressive strained silicon germanium epitaxial layer 30 can be formed thereover. The layer 30 may be extremely thin and may be coherently grown directly on the substantially silicon substrate 12 in one embodiment. As a result, the silicon germanium epitaxial layer 30 is biaxially compressively strained. The compressive strain is exerted in the channel area through global biaxial coherency stress from the silicon substrate 12 due to the lattice constant mismatch between the silicon substrate 12 and the thin silicon germanium epitaxial layer 30.

Then, as shown in FIG. 8, a gate structure including a high dielectric constant gate dielectric 36 and a metal gate electrode 34 may be formed on the layer 30 in one embodiment. Sidewall spacers 32 can be defined. Then, source and drain regions 20 can be formed. The source and drain regions 20 may be formed by epitaxial deposition of silicon germanium material. As a result, uniaxial strain is also added in the layer 30 as a result of local uniaxial stress exerted by the silicon germanium source and drain regions 20 on the two sides of the transistor channel.

The gate electrode 34 may be a metal which is workfunction matched to the silicon germanium epitaxial layer 30, or a combination of workfunction matched metal at the bottom and a polysilicon in the upper portion of layer 34. The gate dielectric 36 can be a high dielectric constant material. The high dielectric constant gate oxide 36 may reduce gate oxide leakage and may reduce the gate oxide to silicon germanium epitaxial layer 30 interface charge.

In some embodiments, the resulting transistor may exhibit enhanced hole mobility at both low and high electric fields because of the coherently strained thin silicon germanium channel. The silicon germanium channel can be operated as a surface channel with the gate dielectric 36 grown directly on the silicon germanium epitaxial layer 30.

The structure shown in FIG. 8 may be compatible with existing complementary metal oxide semiconductor process flows, with the addition of a short silicon germanium epitaxial deposition that can be grown selectively only in the PMOS transistor regions. Alternatively, the silicon germanium epitaxial layer 30 can be removed from the NMOS region after blanket deposition, leaving the silicon germanium epitaxial layer 30 only in the PMOS regions. The use of an ultra-thin silicon germanium epitaxial layer 30 may have little or no self-heating impact in many embodiments.

In one embodiment, the silicon germanium epitaxial layer 30 may have the formula Si₁₋ₓGeₓ where x is from 10 to 50 percent. The layer 30 may be from 25 to 1000 Angstroms thick in one embodiment of the present invention.

The thin silicon germanium epitaxial layer 30 is grown on a silicon substrate 12 with the germanium concentration between 10 and 50 percent and a thickness between 25 Angstroms and 1000 Angstroms. The gate dielectric 36 may be a high dielectric constant gate dielectric such as hafnium dioxide or zirconium dioxide. The gate electrode 34 may be a metal gate, such as titanium nitride or tantalum nitride, with or without a polysilicon cap. The workfunction of the gate electrode 34 may be matched to the silicon germanium channel. The dielectric 36 may be formed directly on the silicon germanium epitaxial layer 30.

Salicide (not shown) may be formed on top of the source/drain regions 20 and/or the gate region in some embodiments. The silicon germanium epitaxial layer 30 may be removed from the NMOS active region by a wet chemical etching down to the silicon bulk surface and then the NMOS devices can be fabricated using standard NMOS process flows.

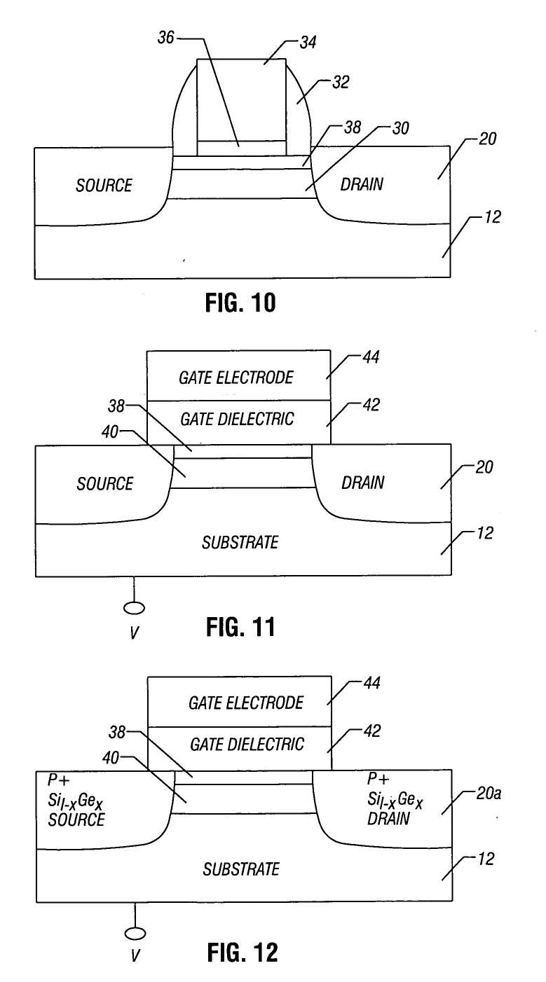

In accordance with another embodiment of the present invention, shown in FIGS. 9 and 10, a hole quantum well is formed under a silicon capping layer 38 in a biaxial compressively strained silicon germanium epitaxial layer 30. Otherwise, the structure may be as shown in FIGS. 7 and 8.

The silicon capping layer 38 creates a quantum well, as well as a surface on which can be grown the gate dielectric 36. The quantum well confines the carriers to the well and so there is less scattering, especially surface scattering. The capping 38, made of silicon, has a wider band gap than the hole quantum well formed by the silicon germanium epitaxial layer 30. The capping layer 38 is not strained since the layer 30 is compressively stained to match the lattice structure of the underlying silicon substrate 12. Thus, the layer 38, of silicon, has the lattice structure which matches the lattice structure of the layer 30 without strain.

A thin silicon germanium epitaxial layer 30 is grown on a silicon substrate 12 with a germanium concentration between about 10 to 50 percent and a thickness between 25 to 1000 Angstroms. This is followed by a thin epitaxial silicon cap growth to form the silicon germanium quantum well structure. The silicon capping layer 38 may have a thickness of between 25 and 200 Angstroms in some embodiments.

The gate dielectric 36, shown in FIG. 10, may be a high dielectric constant material and the gate electrode 34 may be a metal gate, as described above, which has a workfunction matched to the silicon/silicon germanium/silicon quantum well. A recess etch of the PMOS source/drain area may be followed by regrowth of the source/drain area with epitaxial silicon germanium, where the germanium concentration is from 10 to 50 percent and the silicon germanium is of the formula Si_{1-y}Ge_{y}. A spacer isolates the source/drain in the gate region. In some embodiments, salicide (not shown) may be formed on top of the source/drain region 20. An NMOS device can be fabricated using any standard NMOS process flow in the NMOS regions.

Referring to FIG. 11, an NMOS or PMOS structure may have a substrate 12 with a source/drain 20, a silicon capping layer 38 over a narrow band gap layer 40. By “narrow band gap,” it is intended to refer to a material having a narrower band gap than the material immediately below. Thus, the layer 40 has a narrower band gap than the substrate 12 in this example. Normally, silicon has a band gap of 1.1 eV. Examples of material for use in the layer 40, over a substrate 12 formed of silicon, include silicon germanium and silicon carbon. Other materials are also possible.

The overlying silicon capping layer 38 may provide a layer from which to grow a gate dielectric 42 if desired.

The structure shown in FIG. 11 includes forward source-substrate bias as indicated by the bias voltage V, situated on the substrate 12, on the source side. Generally, it is desirable to increase circuit performance by increasing “on” current without increasing “off” current. In a low power circuit design, forward bias may be applied across the source-substrate junction when the transistor is “on.” When the transistor is “off,” this bias may be set to zero. The forward bias lowers the threshold voltage under the “on” condition when compared to the threshold voltage under the “off” condition. Thus, a higher “on” current is achieved without increasing the “off” current. The combination of the forward source-substrate bias with a narrow band gap layer 40 has an advantageous threshold lowering effect when the gate is on.

The narrow band gap layer 40 effectively increases the sensitivity of the channel threshold voltage to source-substrate bias. The rate of change of threshold voltage, with respect to source-substrate bias may be determined as a function of band gap of the layer 40. For a given change in source-substrate bias V, a narrow band gap layer 40 may result in a higher reduction in “on” threshold voltage, resulting in higher drive current.

Using a narrower band gap layer 40 reduces the built-in potential of the source-channel junction. Thus, devices may have a higher off current. In order to match the off current, the halo doping concentration may be made higher.

In one embodiment, using silicon germanium in layer 40, the threshold gain may be higher in PMOS transistors than NMOS transistors. The higher gain in PMOS transistors may be due to the fact that band offset at the silicon germanium interface lies mostly in the valence band. The valence band discontinuity tends to confine the holes in the narrow band gap layer 40, increasing the peak density of the inversion charge. However, using a different narrow band gap material, such as silicon carbon with band offsets mostly in the conduction band, may result in higher gain in NMOS devices as well.

In one embodiment, shown in FIG. 11, the material 40 may be silicon germanium of the formula Si_{1-y}Ge_{y}. The layer 40 may be positioned directly over a silicon substrate 12 or an intervening relaxed silicon germanium layer may be provided. A silicon layer on top of a silicon germanium layer may induce a biaxial stress which improves drive current in NMOS transistors, but provides little gain for PMOS transistors at high gate fields.

In some embodiments of the present invention, the narrow band gap layer 40 may have a thickness of below 300 Angstroms. This thin, narrow band gap layer 40 reduces self-heating. Generally, the germanium concentration of the narrow band gap layer 40 improves performance. Germanium concentrations of greater than 40 percent may be advantageous, but germanium concentrations beyond 10 percent may be effective in some cases.

Advantageously, the silicon capping layer 38 is made sufficiently thin to avoid unduly spacing the layer 40 from the gate electrode 44. For example, the silicon capping layer 38 may be approximately 10 Angstroms thick in one embodiment. In general, it is desired that the band gap of the layer 40 be less than the band gap of the underlying material, such as the substrate 12, in the configuration shown in FIG. 11.

Referring to FIG. 12, a uniaxial strained PMOS structure is illustrated. It may have uniaxial strain due to the formation of epitaxially deposited narrow band gap sources and drains 20a. The sources and drains 20a and the layer 40 may be the same or different materials. For example, the source/drains 20a may be epitaxial silicon germanium of the formula Si₁₋ₓGeₓ. The layer 40 may be silicon germanium of the formula Si_{1-y}Ge_{y}. By making x greater than y, the contribution of uniaxial strain dominates over the biaxial strain that may arise in some embodiments from depositing material, such as silicon germanium, over silicon substrates.

In some embodiments, it may be advantageous to provide an interface (not shown) between the substrate 12 and the layer 40. The interface may exhibit a decreasing germanium concentration to reduce biaxial strain.

In another embodiment of the present invention, the layer 40, shown in FIGS. 11 and 12, may be formed by ion implantation. For example, a silicon substrate may be implanted with germanium or carbon to form an implanted narrow band gap layer 40.

In the embodiments of FIGS. 11 and 12, any desired materials may be used for the gate electrode 44 and the gate dielectric 42. Any desired NMOS transistor can be fabricated with the PMOS transistor depicted in FIG. 12.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
forming a biaxially strained silicon layer having a thickness greater than 500 Angstroms; and
forming a source and drain in said biaxially strained silicon layer.

2. The method of claim 1 including forming said silicon layer to have a thermal conductivity greater than or equal to 0.2 W/(cm. deg.).

3. The method of claim 1 including forming a gate oxide directly on said silicon layer.

4. The method of claim 3 including forming said gate oxide of a material having a dielectric constant greater than 10.

5. The method of claim 1 including forming said silicon layer of a relaxed silicon germanium layer and forming said relaxed silicon germanium layer over a graded silicon germanium layer on a silicon substrate.

6. A transistor comprising:
a biaxially strained silicon layer having a thickness of greater than 500 Angstroms; and
a source and drain in said layer.

7. The transistor of claim 6 wherein said silicon layer has a thermal conductivity greater than 0.2 W/(cm. deg.).

8. The transistor of claim 6 including a gate dielectric formed directly on said silicon layer.

9. The transistor of claim 8 wherein said gate dielectric has a dielectric constant greater than 10.

10. The transistor of claim 6 including a silicon substrate, a graded silicon germanium layer over said substrate, and a relaxed silicon germanium layer over said graded silicon germanium layer.

11. A method comprising:
forming a PMOS transistor having a biaxially strained and uniaxially strained silicon germanium epitaxial layer.

12. The method of claim 11 including forming a gate dielectric directly on said epitaxial layer.

13. The method of claim 12 including forming said epitaxial layer over a silicon substrate to create biaxial compressive strain.

14. The method of claim 13 including forming an epitaxial silicon germanium source/drain to create uniaxial strain.

15. The method of claim 11 including forming a silicon capping layer over said germanium epitaxial layer.

16. A transistor comprising:
a uniaxially and biaxially strained epitaxial layer; and
a p-type source/drain formed in said epitaxial layer.

17. The transistor of claim 16 wherein said transistor is a PMOS transistor.

18. The transistor of claim 17 including a gate dielectric directly on said epitaxial layer.

19. The transistor of claim 16 including a semiconductor substrate, said epitaxial layer formed directly on said semiconductor substrate.

20. The transistor of claim 16 including a silicon capping layer over said epitaxial layer.

21. A method comprising:
forming a first layer over a substrate, said first layer having a narrower band gap than said substrate and said first layer being less than 300 Angstroms thick; and forming a gate electrode over said first layer.

22. The method of claim 21 including forming a silicon capping layer over said first layer.

23. The method of claim 22 including growing a gate electrode on said silicon capping layer.

24. The method of claim 21 including using source substrate biasing.

25. The method of claim 21 including forming a silicon germanium source/drain and forming said first layer of silicon germanium and causing the germanium concentration of said source/drain to be higher than the germanium concentration of said first layer.

26. A transistor comprising:
a substrate;
a first layer formed over said substrate, said first layer being less than 300 Angstroms thick and having a band gap narrower than the band gap of said substrate; and
a gate electrode over said first layer.

27. The transistor of claim 26 wherein said transistor includes a silicon capping layer over said first layer and a silicon dioxide gate dielectric over said silicon capping layer.

28. The transistor of claim 26 including source substrate bias.

29. The transistor of claim 26 including an epitaxial source/drain.

30. The transistor of claim 29 wherein said first layer includes silicon germanium, said epitaxial source/drain includes silicon germanium, and said germanium concentration in said source/drain is higher than the germanium concentration in said first layer.
